(19) United States
(12) Patent Application Publication
(10) Pub. No.: US 2015/0263155 A1
(43) Pub. Date: Sep. 17, 2015

(54) SEMICONDUCTOR DEVICE

(71) Applicant: KABUSHIKI KAISHA TOSHIBA, Tokyo (JP)

(72) Inventor: Hidetoshi FUJIMOTO, Kawasaki Kanagawa (JP)

(21) Appl. No.: 14/475,533

(22) Filed: Sep. 2, 2014

(30) Foreign Application Priority Data
Mar. 14, 2014 (JP) 2014-052733

(51) Int. Cl. H01L 29/778; H01L 29/205; H01L 29/20; H01L 29/207

(52) U.S. Cl. CPC H01L 29/7787; H01L 29/207; H01L 29/205; H01L 29/2003

(57) ABSTRACT

A semiconductor device includes a first nitride semiconductor layer and a second nitride semiconductor layer having a band gap wider than the first nitride semiconductor layer. Source and drain electrodes are provided on the second nitride semiconductor layer. A third nitride semiconductor layer is provided between the source electrode and the drain electrode on the second nitride semiconductor layer. The third nitride semiconductor layer has an impurity concentration of 1×10¹⁷ atoms/cm³ or less, and a band gap narrower than the second nitride semiconductor layer. A p-type fourth nitride semiconductor layer is provided on the third nitride semiconductor layer, and a gate electrode is provided on the fourth nitride semiconductor layer.

### CROSS-REFERENCE TO RELATED APPLICATION

This application is based upon and claims the benefit of priority from Japanese Patent Application No. 2014-052733, filed Mar. 14, 2014, the entire contents of which are incorporated herein by reference.

### FIELD

Embodiments described herein relate generally to a semiconductor device.

### BACKGROUND

Circuits such as switching power supplies and inverters use semiconductor devices such as switching elements and diodes. These semiconductor devices are required to have high breakdown voltage and low on-resistance. For this reason, between breakdown voltage and on-resistance, there are trade-offs which are determined by the materials of devices.

With advancement of technological development, there have been implemented semiconductor devices having low on-resistance close to the limit of silicon, which is a main material of these devices. In order to further reduce on-resistance, it is necessary to change the materials of devices. If a nitride semiconductor such as GaN or AlGaN, or a wide band gap semiconductor such as silicon carbide (SiC) is used as a switching element material, it is possible to improve the trade-offs discussed above, and to reduce on-resistance.

Devices using nitride semiconductors such as GaN and AlGaN are, in general, devices having low on-resistance, and an example of such the devices includes a high electron mobility transistor (HEMT) using a hetero-junction structure of AlGaN and GaN. The HEMT realizes low on-resistance by high mobility of a channel formed at the hetero-junction, and high electron concentration which is generated by polarization.

However, since the HEMT generates electrons by polarization, electrons exist in high concentration under the gate electrode. For this reason, in general, the HEMT becomes a normally-on type device whose gate threshold voltage is negative. For a safe operation, it is preferred to incorporate a normally-off type device having a gate threshold voltage that is positive. For example, in order to implement a normally-off type device, a p-type semiconductor layer can be provided below the gate electrode. But, in this method, an increase in gate leakage current is a problem.

### DESCRIPTION OF THE DRAWINGS

FIG. 1 is a schematic cross-sectional view illustrating a semiconductor device according to a first embodiment.

FIG. 2 is a schematic cross-sectional view illustrating a semiconductor device according to a second embodiment.

FIG. 3 is a schematic cross-sectional view illustrating a semiconductor device of a modified example according to the second embodiment.

### DETAILED DESCRIPTION

An embodiment provides a semiconductor device that has a low gate leakage current.

In general, according to one embodiment, a semiconductor device includes: a first nitride semiconductor layer; a second nitride semiconductor layer on the first nitride semiconductor layer and having a band gap wider than a band gap of the first nitride semiconductor layer. A source and a drain electrode are spaced apart on the second nitride semiconductor layer. A third nitride semiconductor layer is on the second nitride semiconductor layer between the source electrode and the drain electrode and has an impurity concentration of 1×10¹⁷ atoms/cm³ or less and a band gap narrower than the band gap of the second nitride semiconductor layer. A p-type fourth nitride semiconductor layer is on the third nitride semiconductor layer. A gate electrode is provided on the fourth nitride semiconductor layer.

In this specification, elements identical or similar to each other are denoted by the same reference symbol, and repeated description of an element may be omitted.

In this specification, the term “nitride semiconductor” means, for example, a GaN-based semiconductor. The term “GaN-based semiconductor” is the general term for semiconductors having a composition such as gallium nitride (GaN), aluminum nitride (AlN) and indium nitride (InN), or an intermediate composition of these materials.

In this specification, the term “undoped” means having no impurities intentionally introduced into the material.

### First Embodiment

A semiconductor device according to the present embodiment includes a first nitride semiconductor layer, a second nitride semiconductor layer that is provided on the first nitride semiconductor layer and has a band gap wider than that of the first nitride semiconductor layer, a source electrode that is provided on the second nitride semiconductor layer, a drain electrode that is provided on the second nitride semiconductor layer, a third nitride semiconductor layer that is provided on the second nitride semiconductor layer between the source electrode and the drain electrode, has an impurity concentration of 1×10¹⁷ atoms/cm³ or less, and has a band gap narrower than that of the second nitride semiconductor layer, a p-type fourth nitride semiconductor layer that is provided on the third nitride semiconductor layer, and a gate electrode that is provided on the fourth nitride semiconductor layer.

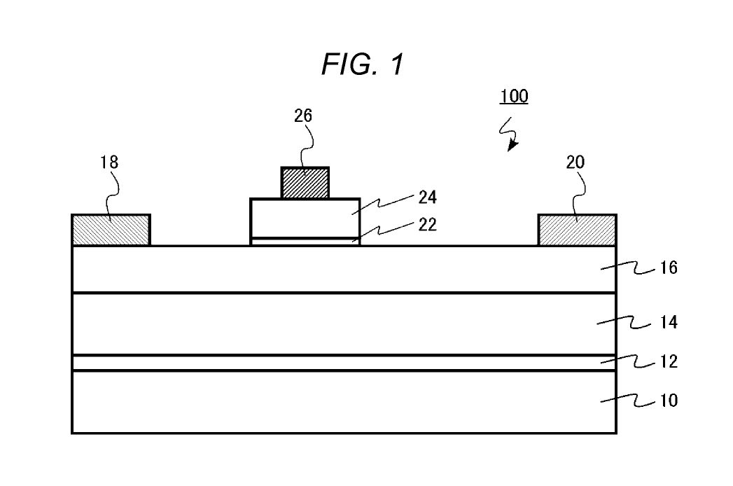

FIG. 1 is a schematically cross-sectional view illustrating the semiconductor device according to the first embodiment. The semiconductor device according to the first embodiment is an HEMT using a GaN-based semiconductor.

As shown in FIG. 1, a semiconductor device (HEMT) 100 includes a substrate 10, a buffer layer 12, a channel layer (a first nitride semiconductor layer) 14, a barrier layer (a second nitride semiconductor layer) 16, a source electrode 18, a drain electrode 20, a first cap layer (a third nitride semiconductor layer) 22, a second cap layer (a fourth nitride semiconductor layer) 24, and a gate electrode 26.

The substrate 10 is formed of, for example, silicon (Si). Besides silicon, for example, sapphire (Al₂O₃) or silicon carbide (SiC) can also be used as the substrate 10.

On the substrate 10, the buffer layer 12 is provided. The buffer layer 12 has a function of relieving lattice mismatch between the substrate 10 and the channel layer 14. The buffer layer 12 is formed of, for example, a multi-layer structure of aluminum gallium nitride (Al_{W}Ga_{1-W}N wherein 0<W<1).

On the buffer layer 12, the channel layer 14 is provided. The channel layer 14 is, for example, an undoped Al_{X}Ga_{1-X}N layer (wherein 0≦X<1). More specifically, the channel layer 14 is, for example, an undoped GaN layer. The channel layer 14 has, for example, a film thickness of equal to or larger than 0.5 μm and equal to or less than 3 μm.

On the channel layer 14, the barrier layer 16 is provided. The band gap of the barrier layer 16 is wider than the band gap of the channel layer 14. The barrier layer 16 is, for example, an undoped Al_{Y}Ga_{1-Y}N layer (wherein 0<Y≦1 and X<Y). More specifically, the barrier layer 16 is, for example, an undoped Al_{0.2}Ga_{0.8}N layer. The barrier layer 16 has, for example, a film thickness of equal to or larger than 20 nm and equal to or less than 50 nm.

An interface between the channel layer 14 and the barrier layer 16 becomes a hetero-junction. During an ON operation of the HEMT 100, a two-dimensional electron gas is formed at the hetero-junction interface, and becomes conductive.

On the barrier layer 16, the source electrode 18 and the drain electrode 20 are formed. The source electrode 18 and the drain electrode 20 are, for example, metal electrodes, and the metal electrodes are electrodes containing, for example, aluminum (Al) as a main component. It is desirable for the source electrode 18 and the drain electrode 20 to be in ohmic contact with the barrier layer 16. The distance between the source electrode 18 and the drain electrode 20 is, for example, about 18 μm.

Between the source electrode 18 and the drain electrode 20 on the barrier layer 16, the first cap layer 22 is provided. The first cap layer 22 is a high-resistance layer and has a function of suppressing the gate leakage current.

The impurity concentration of the first cap layer 22 is equal to or less than 1×10¹⁷ atoms/cm³. In the first cap layer 22, there is at least a region having the impurity concentration of equal to or less than 1×10¹⁷ atoms/cm³. In order to make the first cap layer 22 have high resistance, it is desirable that the impurity concentration of the first cap layer 22 is equal to or less than 1×10¹⁶ atoms/cm³, and it is more desirable that the impurity concentration of the first cap layer 22 is equal to or less than 1×10¹⁵ atoms/cm³.

The impurity concentration can be analyzed, for example, by secondary ion mass spectrometry (SIMS).

The band gap of the first cap layer 22 is lower than the band gap of the channel layer 14. The first cap layer 22 is, for example, an undoped Al_{Z}Ga_{1-Z}N layer (wherein 0≦Z<1 and Y>Z). More specifically, the first cap layer 22 is, for example, an undoped GaN layer. The first cap layer 22 has, for example, a film thickness of equal to or larger than 1 nm and equal to or less than 10 nm. The first cap layer 22 is a single crystal.

On the first cap layer 22, the p-type second cap layer 24 is provided. The p-type second cap layer 24 has a function of raising the potential of the channel layer 14, thereby increasing the threshold voltage of the HEMT 100.

The second cap layer 24 is, for example, a p-type Al_{U}Ga_{1-U}N layer (wherein 0≦U<1). More specifically, the second cap layer 24 is, for example, a p-type GaN layer. The second cap layer 24 has, for example, a film thickness of equal to or larger than 5 nm and equal to or less than 500 nm.

The p-type impurity contained in the second cap layer 24 is, for example, magnesium (Mg). In order to raise the potential of the channel layer 14, it is desirable that a concentration of the p-type impurity in the second cap layer 24 is equal to or larger than the 1×10¹⁸ atoms/cm³, and it is more desirable that the concentration of the p-type impurity in the second cap layer 24 is equal to or larger than 1×10¹⁹ atoms/cm³. The second cap layer 24 is a single crystal.

On the second cap layer 24, the gate electrode 26 is provided. The gate electrode 26 is, for example, a metal electrode. The metal electrode is, for example, an electrode mainly having a laminate structure of platinum (Pt) and gold (Au). It is desirable that the gate electrode 26 is in ohmic contact with the second cap layer 24.

An example of a method for manufacturing the semiconductor device according to the first embodiment will be described.

First, the substrate 10, for example, a Si substrate is prepared. Next, the buffer layer 12 is grown on the Si substrate, for example, by epitaxial growth.

Next, on the buffer layer 12, undoped GaN to be the channel layer 14, and undoped Al_{0.2}Ga_{0.8}N to be the barrier layer 16 are formed by the epitaxial growth.

Next, undoped GaN to be the first cap layer 22, and p-type GaN to be the second cap layer 24 are sequentially formed by the epitaxial growth. For example, GaN precursor gases are supplied to an epitaxial growth apparatus in which the substrate 10 is held, whereby undoped GaN is formed on the substrate.

Thereafter, Mg and GaN precursor gases are supplied to the epitaxial growth apparatus, whereby undoped GaN and p-type GaN are sequentially formed. For example, an insulating film which is to be subjected to patterning may be formed on the surface of the barrier layer 16, then patterned, whereby the first cap layer 22 and the second cap layer 24 may be selectively grown on the surface of the barrier layer 16.

Next, on the surface of the barrier layer 16, the source electrode 18 and the drain electrode 20 are formed by forming and patterning a metal layer. Also, on the second cap layer 24, the gate electrode 26 is formed by forming and patterning a metal layer.

The semiconductor device 100 shown in FIG. 1 can be manufactured by the above-described manufacturing method.

Subsequently, the operations and effects of the semiconductor device 100 will be described.

In the HEMT 100 according to the first embodiment, since the p-type second cap layer 24 exists immediately below the gate electrode 26, the potential of the channel layer 14 is raised. Therefore, generation of a two-dimensional electron gas is suppressed, and the threshold value of the HEMT 100 increases as compared to a case where the second cap layer 24 does not exist. When the energy of the lower end of the conduction band of the hetero-junction interface becomes higher than the Fermi level, even when the gate voltage is 0 V, the channel layer 14 is depleted, whereby the HEMT 100 has a normally-off operation.

However, if a positive voltage is applied to the gate electrode in order to operate the HEMT 100, a forward voltage is applied to the junction of the barrier layer 16 and the p-type second cap layer 24 between the gate electrode 26 and the source electrode 18 grounded. For this reason, there is a risk that the gate leakage current could increase.

In the first embodiment, the first cap layer 22 having a film thickness less than that of the p-type second cap layer 24 and a low p-type impurity concentration is interposed between the barrier layer 16 and the second cap layer 24. Therefore, since the first cap layer 22 has high resistance, the gate leakage current is suppressed.

Also, the film thickness of the first cap layer 22 is equal to or larger than 1 nm and equal to or less than 10 nm. It is desirable, in some embodiments, that the film thickness of the first cap layer 22 is equal to or larger than 2 nm and equal to and less than 6 nm.

If the film thickness of the first cap layer 22 falls below the above-described range, the resistance of the first cap layer 22 decreases, and thus there is a risk that the effect of suppressing the gate leakage current could not be sufficiently achieved. Also, if the film thickness of the first cap layer 22 exceeds the above-described range, there is a risk that the potential of the channel layer 14 could not be sufficiently raised by the p-type second cap layer 24. That is, since the p-type second cap layer 24 raises the potential of the first cap layer 22, there is a risk that the potential of the channel layer 14 could not be finally and sufficiently raised for conductive operations if the first cap layer is too thick.

As described above, according to the first embodiment, the HEMT 100 which realizes the normally-off operation and suppressing of the gate leakage current is provided.

### Second Embodiment

A semiconductor device according to the second embodiment that the third nitride semiconductor layer is provided on bottom and sides of a recess whose the bottom and sides are positioned in the second nitride semiconductor layer.

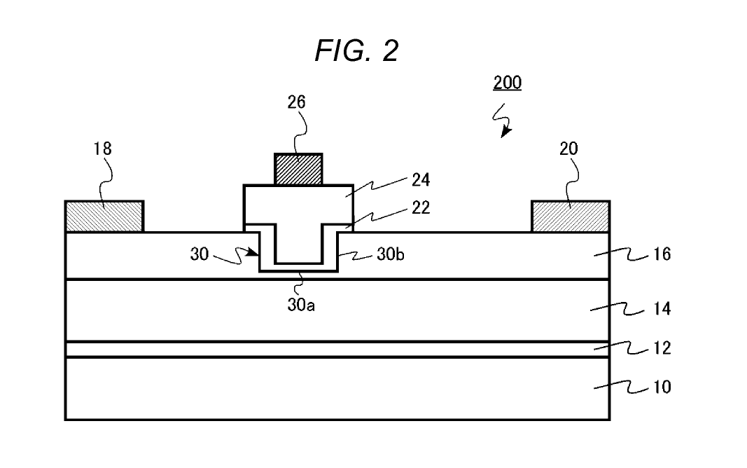

FIG. 2 is a schematically cross-sectional view illustrating the semiconductor device according to the second embodiment. The semiconductor device according to the present embodiment is an HEMT using a GaN-based semiconductor.

As shown in FIG. 2, a semiconductor device (HEMT) 200 includes a substrate 10, a buffer layer 12, a channel layer (a first nitride semiconductor layer) 14, a barrier layer (a second nitride semiconductor layer) 16, a source electrode 18, a drain electrode 20, a first cap layer (a third nitride semiconductor layer) 22, a second cap layer (a fourth nitride semiconductor layer) 24, a gate electrode 26, and a recess 30.

In the HEMT 200, the first cap layer 22 and the second cap layer 24 are provided in the recess (trench) 30 formed in the barrier layer 16. The bottom 30a and sides 30b of the recess 30 are positioned in the barrier layer.

The HEMT 200 has a so-called recess structure. The first cap layer 22 is provided on the bottom 30a and sides 30b of the recess 30.

The HEMT 200 can be manufactured by a method which is the same as that in the first embodiment except that before the first cap layer 22 and the second cap layer 24 are formed, the recess 30 is formed in the surface of the barrier layer 16 by etching, for example.

Since the HEMT 200 has the p-type second cap layer 24, it is possible to increase the threshold value of the transistor. Also, since the HEMT 200 has the first cap layer 22 having high resistance, the gate leakage current is suppressed.

Also, since the HEMT 200 has the recess structure, a portion of the barrier layer 16 positioned below the gate electrode 26 becomes thin. Therefore, the quantity of piezoelectric polarization decreases, and the concentration of the two-dimensional electron gas below the gate electrode 26 decreases. Therefore, it becomes somewhat easier to realize a normally-off operation.

It is desirable, though not necessarily required, that the film thickness of the first cap layer 22 on the sides 30b is larger than the film thickness of the first cap layer 22 on the bottom 30a as shown in FIG. 2. According to this configuration, the first cap layer 22 on the bottom 30a has a thickness sufficient reduce gate leakage current of the HEMT 200, but is not so thick as to prevent a necessary increase in the threshold voltage of the HEMT 200 for providing normally-off operation. Meanwhile, since the film thickness on the first cap layer 22 on the sides 30b is relatively large, it is possible to suppress the gate leakage current at the sides 30b.

Also, it is preferred that the interface between the first cap layer 22 and the second cap layer 24 is positioned closer to the gate electrode 26 than to the opposite surface of the barrier layer 16 to the channel layer 14 as shown in FIG. 2. According to this configuration, since the first cap layer 22 becomes thinner at the upper corners of the recess 30, it is possible to suppress increases in the gate leakage current. For example a first portion of the interface of the first and second cap layers (22 & 24) may be outside of the recess, such that this first portion is not between the side surfaces of the recess and is closer to the gate electrode 26 than to an interface of the first and second nitride semiconductor layers (e.g., barrier layer 16 and channel layer 14).

Also, it is preferred that the edge portions of the first cap layer 22 be positioned on the surface of the barrier layer 16 other than within the recess 30. According to this configuration, it is possible to improve the margin (tolerance) of alignment between the recess 30 and the first cap layer 22 during manufacturing, and to implement the HEMT 200 having stable characteristics. In addition, since the first cap layer 22 becomes thinner at the upper corners of the recess 30, it is possible to suppress increase of the gate leakage current.

### Modified Example

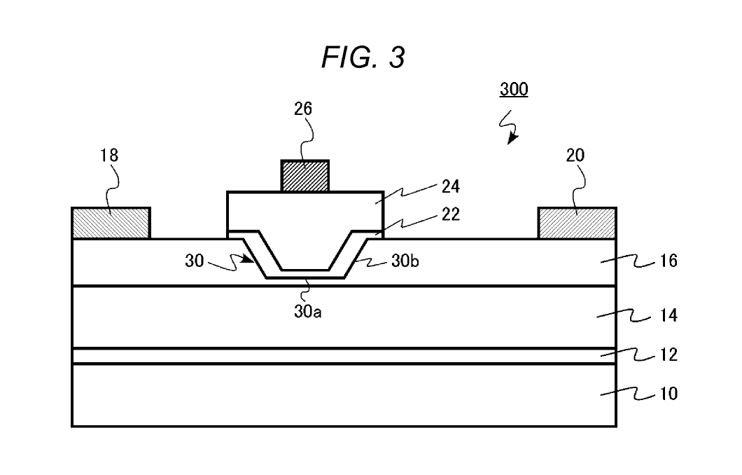

FIG. 3 is a schematically cross-sectional view illustrating a semiconductor device as a modified example according to the second embodiment. In an HEMT 300, as shown in FIG. 3, the sides 30b of a recess 30 have an inclination angle of less than 90 degrees with respect to the interface between the channel layer (the first nitride semiconductor layer) 14 and the barrier layer (the second nitride semiconductor layer) 16.

Since the sides 30b are inclined, it becomes easy to embedded (coat) the recess 30 with the first cap layer 22 and the second cap layer 24. Therefore, it also becomes easier to make the film thickness of the first cap layer 22 on the sides 30b larger than the film thickness of the first cap layer 22 on the bottom 30a.

As described above, it is possible to provide the HEMT 200 and the HEMT 300 which have a normally-off operation and low gate leakage current. Further, since the HEMTs have recess structures, it becomes relatively easy to provide the normally-off operation.

In the described example embodiments, GaN and AlGaN have been used as examples of the material of the nitride semiconductor layers. However, for example, InGaN, InAlN, and InAlGaN containing indium (In) can also be applied to embodiments of the present disclosure. Also, AlN can be the material of the nitride semiconductor layers in embodiments of the present disclosure.

Also, in the example embodiments, a barrier layer, comprising an undoped AlGaN layer has been used. However, an n-type AlGaN layer can also be used as a barrier layer material.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first nitride semiconductor layer;
a second nitride semiconductor layer on the first nitride semiconductor layer and having a band gap that is wider than a band gap of the first nitride semiconductor layer;
a source electrode and a drain electrode spaced apart on the second nitride semiconductor layer;
a third nitride semiconductor layer between the source and drain electrodes on the second nitride semiconductor layer and having an impurity concentration less than or equal to 1×10¹⁷ atoms/cm³ and a band gap that is narrower than the band gap of the second nitride semiconductor layer;
a fourth nitride semiconductor layer of a p-type conductivity and on the third nitride semiconductor layer, the third nitride semiconductor being between the second and the fourth nitride semiconductor layers; and
a gate electrode on the fourth nitride semiconductor layer, the fourth nitride semiconductor layer being between the gate electrode and the third semiconductor layer.

2. The semiconductor device according to claim 1, wherein a film thickness of the third nitride semiconductor layer has a value that is equal to or greater than 1 nm and equal to or less than 10 nm.

3. The semiconductor device according to claim 1, wherein a p-type impurity concentration of the fourth nitride semiconductor layer is equal to or greater than 1×10¹⁸ atoms/cm³.

4. The semiconductor device according to claim 1, wherein the third nitride semiconductor layer is a single crystal layer, and the fourth nitride semiconductor layer is a single crystal layer.

5. The semiconductor device according to claim 1, wherein the second nitride semiconductor layer has a recess formed therein, the recess having a bottom surface and side surfaces formed by the second nitride semiconductor layer, the third nitride semiconductor layer being disposed on the bottom surface and side surfaces of the recess.

6. The semiconductor device according to claim 5, wherein a film thickness, in a direction normal to the side surfaces of the recess, of a portion of the third nitride semiconductor layer disposed on the side surfaces of the recess is greater than a film thickness, in a direction normal to the bottom surface of the recess, of a portion of the third nitride semiconductor layer disposed on the bottom surface of the recess.

7. The semiconductor device according to claim 5, wherein the side surfaces of the recess have an inclination angle of less than 90 degrees with respect to an interface between the first nitride semiconductor layer and the second nitride semiconductor layer.

8. The semiconductor device according to claim 5, wherein a first portion of an interface of the third and fourth nitride semiconductor layers is outside of the recess, such that the first portion is not between the side surfaces of the recess and is closer to the gate electrode than to an interface of the first and second nitride semiconductor layers.

9. The semiconductor device according to claim 1, wherein the fourth nitride semiconductor layer includes magnesium (Mg) as a p-type impurity.

10. The semiconductor device according to claim 1, wherein
the first nitride semiconductor layer comprises Al_{X}Ga_{1-X}N (wherein 0≦X<1),
the second nitride semiconductor layer comprises Al_{Y}Ga_{1-Y}N (wherein 0<Y≦1 and X<Y),
the third nitride semiconductor layer comprises Al_{Z}Ga_{1-Z}N (wherein 0≦Z<1 and Y>Z), and
the fourth nitride semiconductor layer comprises Al_{U}Ga_{1-U}N (wherein 0≦U<1).

11. A semiconductor device, comprising:
a first nitride semiconductor layer;
a second nitride semiconductor layer on the first nitride semiconductor layer and having a band gap that is wider than a band gap of the first nitride semiconductor layer;
a source electrode and a drain electrode spaced apart on the second nitride semiconductor layer;
a third nitride semiconductor layer between the source and drain electrodes on the second nitride semiconductor layer and having an impurity concentration less than or equal to 1×10¹⁷ atoms/cm³ and a band gap narrower than the band gap of the second nitride semiconductor layer;
a fourth nitride semiconductor layer of a p-type conductivity and on the third nitride semiconductor layer, the fourth nitride semiconductor layer having a p-type impurity concentration equal to or greater than 1×10¹⁸ atoms/cm³, the third nitride semiconductor being between the second and the fourth nitride semiconductor layers; and
a gate electrode on the fourth nitride semiconductor layer, the fourth nitride semiconductor layer being between the gate electrode and the third semiconductor layer, wherein
a film thickness of the third nitride semiconductor layer has a value that is equal to or greater than 1 nm and equal to or less than 10 nm,
the third nitride semiconductor layer is a single crystal layer, and
the fourth nitride semiconductor layer is a single crystal layer.

12. The semiconductor device according to claim 11, wherein
the first nitride semiconductor layer comprises Al_{X}Ga_{1-X}N (wherein 0≦X<1),
the second nitride semiconductor layer comprises Al_{Y}Ga_{1-Y}N (wherein 0<Y≦1 and X<Y),
the third nitride semiconductor layer comprises Al_{Z}Ga_{1-Z}N (wherein 0≦Z<1 and Y>Z), and
the fourth nitride semiconductor layer comprises Al_{U}Ga_{1-U}N (wherein 0≦U<1).

13. The semiconductor device according to claim 12, wherein the fourth nitride semiconductor layer includes magnesium (Mg) as a p-type impurity.

14. The semiconductor device according to claim 11, wherein the second nitride semiconductor layer has a recess formed therein, the second nitride semiconductor layer forming a bottom surface and side surfaces of the recess, the third nitride semiconductor layer being disposed on the bottom surface and side surfaces of the recess.

15. A semiconductor device, comprising:
a first nitride semiconductor material;
a second nitride semiconductor material in direct contact with the first nitride semiconductor material at a first interface and having a band gap that is wider than a band gap of the first nitride semiconductor material;
a source electrode and a drain electrode in direct contact with second nitride semiconductor material at a first surface opposite the first interface, the source and drain electrodes spaced apart on the first surface;
a third nitride semiconductor material indirect contact with the first surface between the source and drain electrodes and having an impurity concentration less than or equal to 1×10¹⁷ atoms/cm³ and a band gap narrower than the band gap of the second nitride semiconductor material;
a fourth nitride semiconductor material in direct contact with the third nitride semiconductor material and separated from the second semiconductor material by the third nitride semiconductor material, the fourth nitride semiconductor material being of a p-type conductivity; and
a gate electrode on the fourth nitride semiconductor material, the gate electrode separated from the third semiconductor material by the fourth nitride semiconductor material.

16. The semiconductor device according to claim 15, wherein
the first nitride semiconductor material comprises Al_{X}Ga_{1-X}N (wherein 0≦X<1),
the second nitride semiconductor material comprises Al_{Y}Ga_{1-Y}N (wherein 0<Y≦1 and X<Y),
the third nitride semiconductor material comprises Al_{Z}Ga_{1-Z}N (wherein 0≦Z<1 and Y>Z), and
the fourth nitride semiconductor material comprises Al_{U}Ga_{1-U}N (wherein 0≦U<1).

17. The semiconductor device according to claim 15, wherein the first surface has a recess portion which extends in to the second nitride semiconductor material towards the first interface, and the third nitride semiconductor material directly contacts the first surface of the second nitride semiconductor material at the recess portion.

18. The semiconductor device according to claim 17, wherein a film thickness of the third nitride semiconductor material is different at a bottom portion of the recess portion and a side portion of the recess portion, the bottom portion of the recess portion being substantially parallel to the first interface, the side portion being at a perpendicular or oblique angle to the first interface.

19. The semiconductor device according to claim 18, wherein the film thickness of the third nitride semiconductor layer has a value that is equal to or greater than 1 nm and equal to or less than 10 nm.

20. The semiconductor device according to claim 17, wherein the recess portion has a tapered shape.
